(19) United States
(12) Patent Application Publication
(10) Pub. No.: US 2015/0021634 A1
(43) Pub. Date: Jan. 22, 2015

(54) DISPLAY UNIT USING LED LIGHT SOURCES

(71) Applicant: ROHM CO., LTD., Kyoto-shi (JP)

(72) Inventors: Takayuki ISHIHARA, Kyoto-shi (JP); Satohiro KIGOSHI, Kyoto-shi (JP)

(21) Appl. No.: 14/330,525

(22) Filed: Jul. 14, 2014

(30) Foreign Application Priority Data
Jul. 22, 2013 (JP) 2013-151888
Jul. 22, 2013 (JP) 2013-151889

(51) Int. Cl. H01L 27/15; H01L 33/58; H01L 33/50

(52) U.S. Cl. CPC H01L 27/156; H01L 33/50; H01L 33/58
USPC 257/88

(57) ABSTRACT

A display unit includes a substrate, a plurality of LED light sources arranged in a matrix on the substrate, and a light blocking layer that blocks at least part of light emitted from the LED light sources. The light blocking layer includes an area that overlaps a region between two adjacent LED light sources among the plurality of LED light sources as viewed in a thickness direction Z of the substrate.

### BACKGROUND OF THE INVENTION

1. Field of the Invention

The present invention relates to a display unit using light emitting diodes (LEDs).

2. Description of the Related Art

Conventionally, dot-matrix display units are used as display units for displaying characters in, for example, electronic appliances. A dot-matrix display unit includes a plurality of LED modules arranged in a matrix. An example of a conventional LED module is disclosed in JP-A-2003-17753. The LED module disclosed in the document includes a module substrate, a first LED chip, a second LED chip, and a third LED chip. The first LED chip emits red light, the second LED chip emits green light, and the third LED chip emits blue light. The red light, the green light and the blue light are combined into white light and then emitted from the LED module.

Such a dot-matrix display unit is required to have an increased resolution (pixel density) in order to display desired images at a higher definition. However, simply increasing the pixel density does not result in displaying high-definition images.

### SUMMARY OF THE INVENTION

The present invention has been proposed under the above circumstances. It is an object of the present invention to provide a technique for displaying high-definition images on a display unit having a desired resolution. Another object of the present invention is to provide a display unit that can be easily manufactured.

A display unit provided according to one aspect of the present invention includes: a substrate; a plurality of LED light sources arranged in a matrix on the substrate; and a first light blocking layer that blocks at least part of light emitted from the plurality of LED light sources. The first light blocking layer includes an area that overlaps a region between two adjacent LED light sources among the plurality of LED light sources as viewed in a thickness direction of the substrate.

According to an embodiment of the present invention, the display unit further includes a fluorescent layer that overlaps the plurality of LED light sources as viewed in the thickness direction of the substrate.

According to an embodiment of the present invention, the display unit further includes a second light blocking layer that blocks at least part of the light emitted from the plurality of LED light sources. The second light blocking layer includes an area that overlaps a region between two adjacent LED light sources among the plurality of LED light sources as viewed in the thickness direction of the substrate.

According to an embodiment of the present invention, a plurality of first openings are formed in the first light blocking layer, and the plurality of first openings respectively overlap the plurality of LED light sources as viewed in the thickness direction of the substrate.

According to an embodiment of the present invention, a plurality of second openings are formed in the second light blocking layer, and the plurality of second openings respectively overlap the plurality of LED light sources as viewed in the thickness direction of the substrate.

According to an embodiment of the present invention, the first openings have a larger areal dimension than the second openings.

According to an embodiment of the present invention, the entirety of each of the second openings is located within a corresponding one of the first openings as viewed in the thickness direction of the substrate.

According to an embodiment of the present invention, the plurality of LED light sources are bare chip LEDs.

According to an embodiment of the present invention, the display unit further includes a light transmitting resin portion interposed between the substrate and the first light blocking layer. The light transmitting resin portion covers the plurality of LED light sources.

According to an embodiment of the present invention, the display unit further includes: a bonding layer; and a wiring pattern formed on the substrate. The wiring pattern and any one of the plurality of LED light sources are bonded to each other via the bonding layer.

According to an embodiment of the present invention, the display unit further includes a wire bonded to the wiring pattern and any one of the LED light sources.

According to an embodiment of the present invention, the display unit further includes a control unit that performs control so as to selectively illuminate the plurality of LED light sources.

Other features and advantages of the present invention will be apparent from the following detailed description with reference to the accompanying drawings.

### BRIEF DESCRIPTION OF THE DRAWINGS

FIG. 1 is a cross- sectional view of a display unit according to a first embodiment of the present invention.

FIG. 2 is a partially enlarged cross-sectional view of the display unit shown in FIG. 1.

FIG. 3 is a partially enlarged plan view of the display unit shown in FIG. 1.

FIG. 4 is a plan view of a wiring pattern formed on a substrate.

FIG. 5 is a cross-sectional view of a variation of the display unit according to the first embodiment.

FIG. 6 is a partially enlarged plan view of the display unit shown in FIG. 5.

FIG. 7 is a cross -sectional view of a display unit according to a second embodiment of the present invention.

FIG. 8 is a partially enlarged plan view of the display unit shown in FIG. 7.

FIG. 9 is a cross- sectional view of a display unit according to a third embodiment of the present invention.

FIG. 10 is a cross-sectional view of a display unit according to a fourth embodiment of the present invention.

FIG. 11 is a cross-sectional view of a display unit according to a fifth embodiment of the present invention.

FIG. 12 is a cross-sectional view of a display unit according to a sixth embodiment of the present invention.

FIG. 13 is a cross-sectional view of a variation of the display unit shown in FIG. 2.

FIG. 14 is a cross-sectional view of a variation of the display unit shown in FIG. 5.

FIG. 15 is a cross-sectional view of a variation of the display unit shown in FIG. 7.

FIG. 16 is a cross-sectional view of a variation of the display unit shown in FIG. 9.

FIG. 17 is a cross-sectional view of a variation of the display unit shown in FIG. 10.

### DETAILED DESCRIPTION OF THE PREFERRED EMBODIMENTS

Hereinafter, embodiments of the present invention will be described with reference to the drawings.

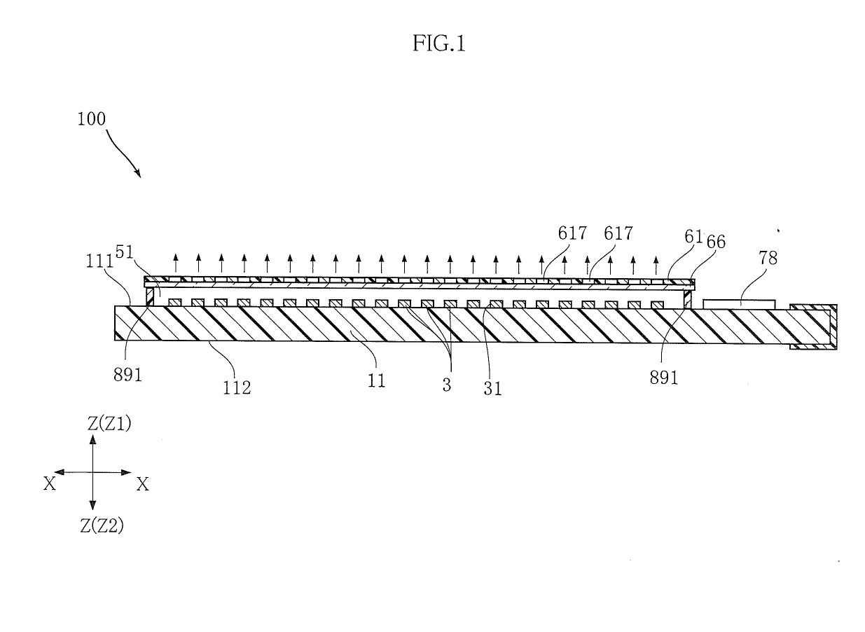

FIGS. 1 to 4 show a display unit according to a first embodiment of the present invention. A display unit 100 shown in the diagrams includes a substrate 11, a wiring pattern 12, a plurality of LED light sources 3 , a light blocking layer (i.e., first light blocking layer) 61, a fluorescent layer 66, a plurality of bonding layers 71, a plurality of wires 77, and a control unit 78.

The display unit 100 is configured to be capable of displaying higher definition images than a conventional display unit having the same pixel density. The display unit 100 is suitable for use as a display unit in, for example, an electronic appliance.

The substrate 11 has an elongated shape extending in one direction. The plurality of LED light sources 3 are disposed on the substrate 11. In the present embodiment, the substrate 11 is made of an insulating material . Examples of the insulating material include ceramic and insulating resin. Examples of ceramic include Al₂O₃, SiC and AlN. An example of insulating resin is glass epoxy resin. Unlike the present embodiment, it is also possible to use a metal plate (for example, an aluminum plate) having an insulating film formed thereon as the substrate 11.

The substrate 11 has a substrate front surface 111 and a substrate back surface 112. The substrate front surface 111 and the substrate back surface 112 are spaced apart from each other in a thickness direction Z and face in opposing directions. To be specific, the substrate front surface 111 faces in a direction Z1, and the substrate back surface 112 faces in a direction Z2. The substrate front surface 111 and the substrate back surface 112 are both flat.

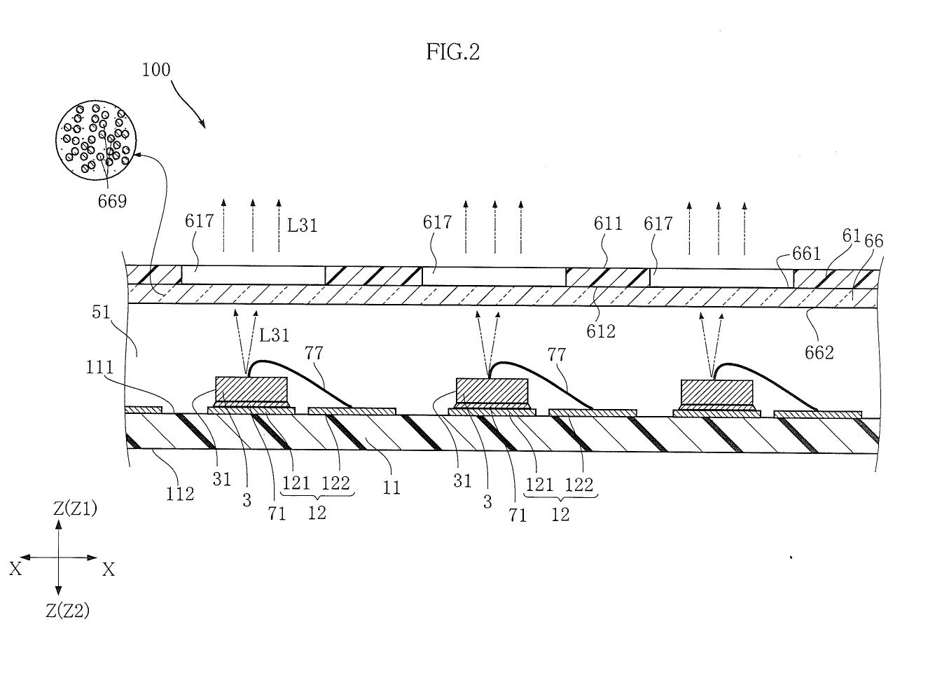

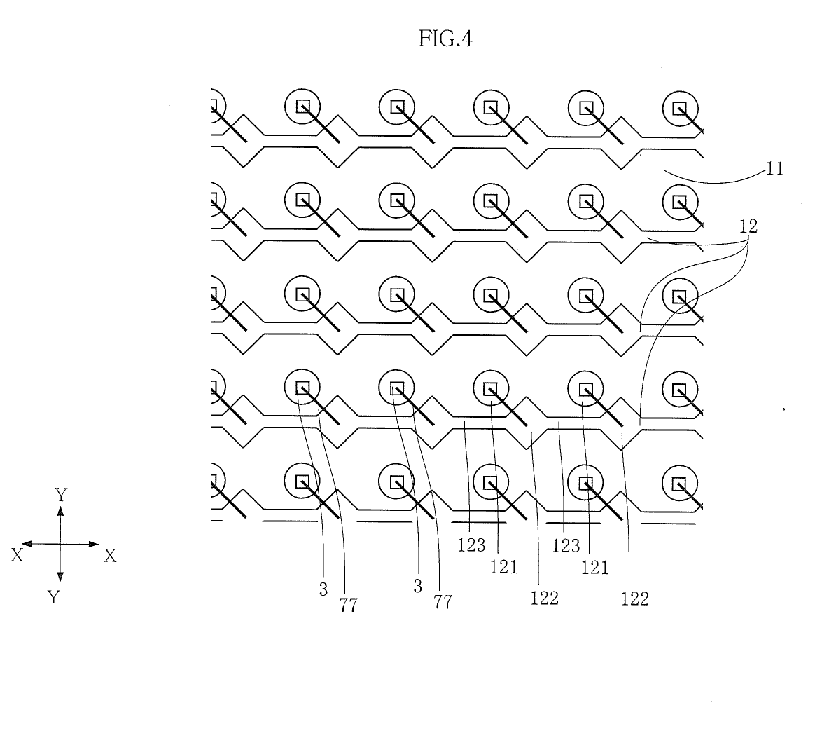

As shown in FIGS. 2 and 4, the wiring pattern 12 is formed on the substrate 11. To be more specific, the wiring pattern 12 is formed on the substrate front surface 111. The wiring pattern 12 functions as a conductive path for supplying power to the LED light sources 3. For this reason, the wiring pattern 12 is made of a conductive material (for example, Au, Ag or Cu). As shown in FIG. 4, the wiring pattern 12 has a predetermined shape in plan view of the substrate 11. The shape of the wiring pattern 12 shown in the diagram is merely an example, and thus the present invention is not limited thereto.

The wiring pattern 12 includes a plurality of die bonding portions 121, a plurality of wire bonding portions 122, and a plurality of connecting portions 123. To be specific, the plurality of die bonding portions 121 are arranged in a matrix. In the present embodiment, the die bonding portions 121 each have a circular shape. Alternatively, the die bonding portions 121 may each have other shapes such as a rectangular shape. The plurality of wire bonding portions 122 are arranged in a matrix. In the present embodiment, the wire bonding portions 122 each have a rectangular shape. Alternatively, the wire bonding portions 122 may each have other shapes such as a circular shape. In the present embodiment, each wire bonding portion 122 is disposed so as to be spaced apart from the corresponding one of the die bonding portions 121 by a predetermined distance. Each of the plurality of connecting portions 123 connects two adjacent wire bonding portions 122 to each other in a first direction X. The connecting portions 123 are each in the shape of a strip extending along the first direction X.

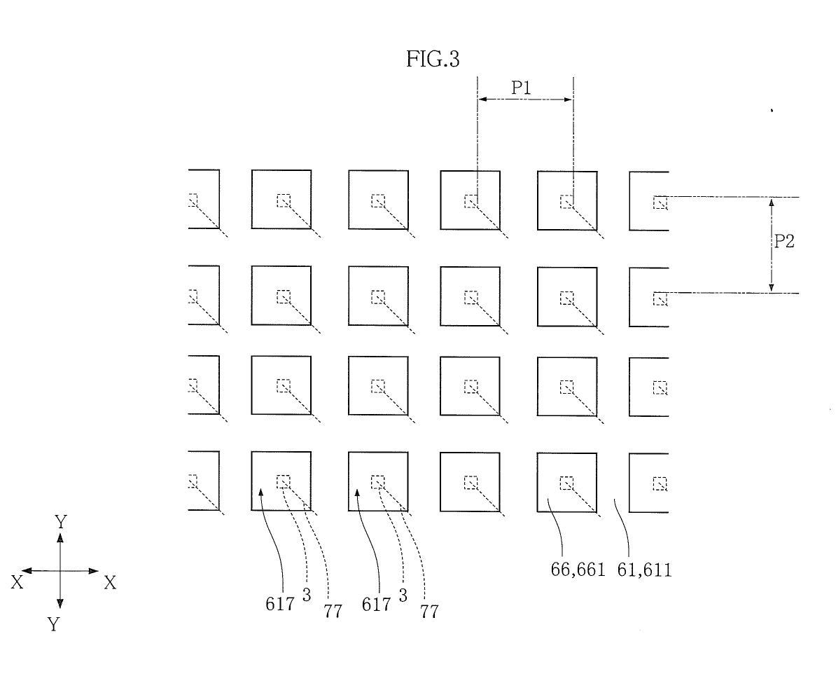

The plurality of LED light sources 3 are supported by the substrate 11 via the wiring pattern 12. Each LED light source 3 is bonded to the corresponding one of the die bonding portions 121. Spacing pitch P1 (see FIG. 3) of the LED light sources 3 in the first direction X is, for example, 0.5 to 1.2 mm. Spacing pitch P2 of the LED light sources 3 in a second direction Y is, for example, 0.5 to 1.2 mm. In the present embodiment, the LED light sources 3 are configured to emit blue light. Needless to say, the present invention is not limited thereto, and the LED light sources 3 may be configured to emit light having a color other than blue.

The number of the plurality of LED light sources 3 is set as appropriate according to the application. In the present embodiment, the plurality of LED light sources 3 are arranged in a matrix of m rows and n columns (each row extending in the first direction X, and each column extending in the second direction Y), where m is an integer of, for example, 5 or more and 7 or less, and n is an integer of, for example, 20 or more and 28 or less.

In the present embodiment, each LED light source 3 is a bare chip LED. To be specific, each LED light source 3 includes an n-type semiconductor layer, an active layer, and a p-type semiconductor layer. The n-type semiconductor layer is laminated on the active layer. The active layer is laminated on the p-type semiconductor layer. The active layer is located between the n-type semiconductor layer and the p-type semiconductor layer. The n-type semiconductor layer, the active layer and the p-type semiconductor layer are made of, for example, GaN. Electrodes (not shown) are formed respectively on the upper and lower surfaces of each LED light source 3.

In the present embodiment, each LED light source 3 includes four side surfaces 31 (see FIG. 2) . The side surfaces 31 face in directions perpendicular to the thickness direction Z of the substrate 11. That is, the normal direction of each side surface 31 is perpendicular to the thickness direction Z.

As shown in FIGS. 2 and 4 and other diagrams, the plurality of wires 77 are bonded to the LED light sources 3 and the wiring pattern 12. To be more specific, one end of each wire 77 is bonded to one of the LED light sources 3 and the other end is bonded to one of the wire bonding portions 122 . Each LED light source 3 is thereby electrically connected to the wiring pattern 12.

As shown in FIG. 2, the plurality of bonding layers 71 are provided to bond the plurality of LED light sources 3 to the wiring pattern 12. To be more specific, each bonding layer 71 is interposed between one of the LED light sources 3 and one of the die bonding portions 121, and is also in direct contact with both the LED light source 3 and the die bonding portion 121. The bonding layers 71 are made of a conductive material (for example, solder or Ag). Unlike the present embodiment, it is also possible to, for example, provide two electrodes on the upper surface of each LED light source 3, and electrically connect the two electrodes to the wiring pattern with the use of two wires. In this case, the bonding layers 71 are not necessarily conductors, and may be made of an insulating material.

The control unit 78 (see FIG. 1) is mounted on the substrate 11, and is configured to perform control so as to selectively illuminate the plurality of LED light sources 3. To be specific, the control unit 78 illuminates or extinguishes each of the plurality of LED light sources 3 based on an image display signal (display image information) input into the display unit 100. In the present embodiment, the control unit 78 receives the display image information by way of a serial signal, and is, for example, a chip with a size of about 5 mm×5 mm in plan view.

As shown in FIG. 2, the fluorescent layer 66 contains fluorescent particles 669. The fluorescent layer 66 is composed mainly of a transparent resin (for example, epoxy resin, silicone resin, polyvinyl-based resin, or the like). The fluorescent layer 66 is disposed so as to be spaced apart from the plurality of LED light sources 3 in the thickness direction Z of the substrate 11. The fluorescent layer 66 is in the form of a film extending parallel to the substrate 11 (or the substrate front surface 111). The fluorescent layer 66 includes portions that overlap the plurality of LED light sources 3 as viewed in the thickness direction Z. In the present embodiment, the fluorescent layer 66 also overlaps a region between each two adjacent LED light sources 3 as viewed in the thickness direction Z. As the fluorescent layer 66, for example, a fluorescent sheet is used. The fluorescent layer 66 has a thickness of, for example, 0.05 to 0.15 mm.

The fluorescent layer 66 has a fluorescent layer front surface 661 and a fluorescent layer' back surface 662. The fluorescent layer front surface 661 and the fluorescent layer back surface 662 face in opposite directions to each other.

To be specific, the fluorescent layer front surface 661 faces in the direction Z1, and the fluorescent layer back surface 662 faces in the direction Z2. The fluorescent layer front surface 661 and the fluorescent layer back surface 662 are both flat. Light L31 emitted from the LED light sources 3 enters the fluorescent layer back surface 662. The light L31 then passes through the fluorescent layer 66 and is emitted from the fluorescent layer front surface 661.

The fluorescent particles 669 are excited by the light emitted from the LED light sources 3, and emit light having a wavelength different from that of the light emitted from the LED light sources 3. In the present embodiment, a configuration is used in which the light emitted from the LED light sources 3 and the light emitted from the fluorescent particles 669 are combined into white light, and the white light is emitted from the fluorescent layer 66. Needless to say, the present invention is not limited thereto, and it is possible to use a configuration in which the light emitted from the LED light sources 3 and the light emitted from the fluorescent particles 669 are combined into light having a color other than white.

The light blocking layer 61 is disposed so as to be spaced apart from the plurality of LED light sources 3 in the thickness direction Z. The light blocking layer 61 is in the form of a film extending parallel to the substrate 11, and has a thickness of, for example, 0.05 to 0.15 mm. The light blocking layer 61 is formed by, for example, printing. The light blocking layer 61 includes portions that each overlap a region between two adjacent LED light sources 3 as viewed in the thickness direction Z.

In the first embodiment, the light blocking layer 61 is opaque, and is configured to completely block the light L31 emitted from the LED light sources 3. Examples of materials for forming the light blocking layer 61 include metals (for example, stainless steel) and PET (polyethylene terephthalate).

Unlike the present embodiment, the light blocking layer 61 may be configured to block part of the light L31 (or in other words, to allow part of the light L31 to pass therethrough). For example, the light blocking layer 61 may be made semi-transparent. A semi-transparent light blocking layer 61 can be formed by using, for example, a material obtained by mixing a pigment or a powder with a light transmitting resin. Needless to say, the light blocking layer 61 may be made semi-transparent by using a method other than the above. For example, the light blocking layer 61 may be provided by attaching a tinting film to a light-transmitting plate-shaped member, or by applying a semi-transparent coating material to a light-transmitting plate-shaped member.

As described above, the light blocking layer used in the lighting unit according to the embodiment of the present invention is configured to block part or all of the light emitted from the light sources. In other words, the light blocking layer is configured to block at least part of the light emitted from the light sources.

In the present embodiment, the light blocking layer 61 has a light blocking layer front surface 611 and a light blocking layer back surface 612. The light blocking layer front surface 611 and the light blocking layer back surface 612 face in opposite directions to each other. To be specific, the light blocking layer front surface 611 faces in the direction Z1, and the light blocking layer back surface 612 faces in the direction Z2. The light blocking layer front surface 611 and the light blocking layer back surface 612 are both flat.

In the present embodiment, the light blocking layer 61 is laminated on the fluorescent layer 66. The light blocking layer 61 and the fluorescent layer 66 are in contact with each other. Also, in the present embodiment, the fluorescent layer 66 is located between the light blocking layer 61 and the substrate 11 in the thickness direction Z of the substrate 11. The light blocking layer 61 is in contact with the fluorescent layer front surface 661 of the fluorescent layer 66.

A plurality of openings (i.e., first openings) 617 are formed in the light blocking layer 61. The plurality of openings 617 each have a rectangular shape. The plurality of openings 617 respectively overlap the plurality of LED light sources 3 as viewed in the thickness direction Z. Each opening 617 has a size of, for example, 0.5 mm×0.5 mm. The fluorescent layer 66 includes an area that overlaps each opening 617 as viewed in the thickness direction Z.

As shown in FIG. 1, the light blocking layer 61 and the fluorescent layer 66 are attached to the substrate 11 via a supporting portion 891.

As shown in FIGS. 1 and 2, the display unit 100 includes a vacant space 51. The plurality of LED light sources 3 are exposed in the vacant space 51. The upper end of the vacant space 51 is defined by the fluorescent layer 66. The spaced distance between the substrate 11 and the fluorescent layer 66 (or the spaced distance between the substrate 11 and the light blocking layer 61) is preferably 0.3 to 0.7 mm. In the present embodiment, the distance from the lower end of the vacant space 51 (the substrate front surface 111) to the upper end of the vacant space 51 (the fluorescent layer back surface 662 of the fluorescent layer 66) is set to be within a range of 0.3 to 0.7 mm.

Functions and advantageous effects of the display unit 100 described above will be described next.

The display unit 100 of the first embodiment includes the light blocking layer 61 that completely blocks the light L31 emitted from the LED light sources 3. The light blocking layer 61 includes areas that each overlap a region between two adjacent LED light sources 3 as Viewed in the thickness direction Z of the substrate 11. With this configuration, the following advantageous effects can be obtained. Specifically, when the display unit 100 during operation is viewed from above in FIG. 1, the areas corresponding to the regions each between two adjacent LED light sources 3 appear darker than those in a conventional display unit. Accordingly, each pixel displayed by the display unit 100 appears clearly as if separated from the surrounding pixels, as a result of which images (characters, graphics and the like) constituted by a plurality of such pixels become clear. For this reason, it is possible to display higher definition images than a conventional display unit while achieving a desired high resolution (pixel density) . The same effects can be obtained by using a semi-transparent light blocking layer 61 configured to block most of the light L31 and allow the remaining part of the light L31 to pass there through.

Also, in the present embodiment, the LED light sources 3 are bare chip LEDs. With this configuration, the spacing pitches (see P1 and P2 shown in FIG. 3) between adjacent LED light sources 3 can be reduced, contributing to an improvement in pixel density.

Also, in the present embodiment, the display unit 100 includes a single piece of fluorescent layer 66 that overlaps the plurality of LED light sources 3 as viewed in the thickness direction Z of the substrate 11. The fluorescent layer 66 is disposed at a position spaced apart from the plurality of LED light sources 3 in the thickness direction Z of the substrate 11. With this configuration, it is unnecessary to form a fluorescent portion that covers each LED light source 3 by, for example, potting, which contributes to the simplification of the production of the display unit 100.

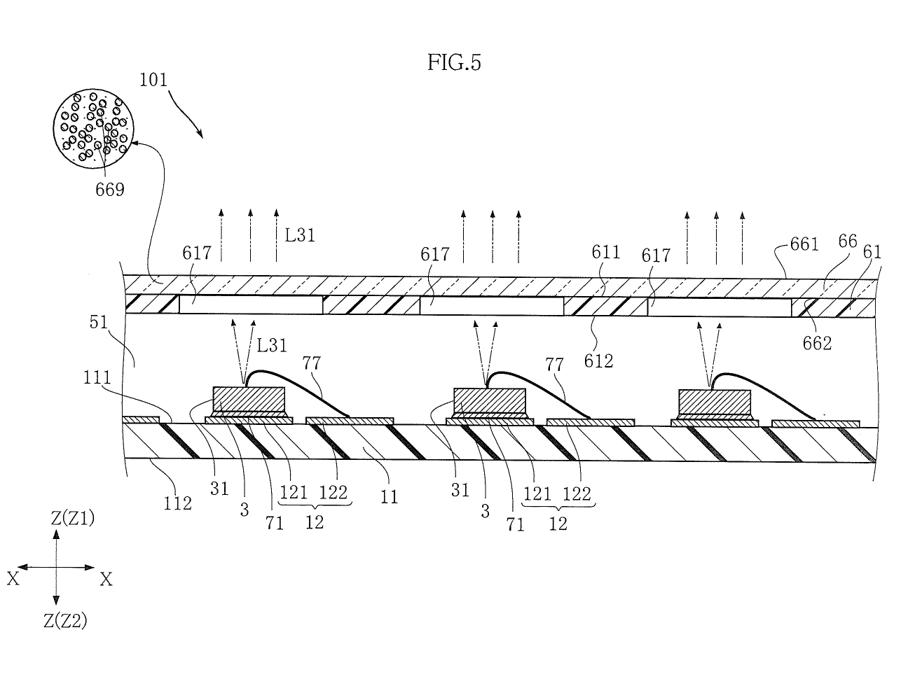

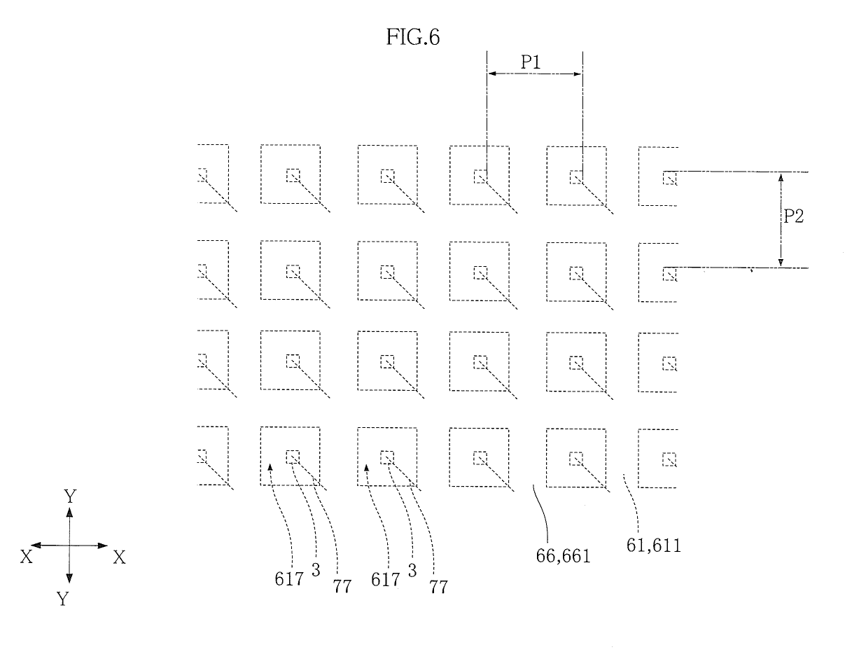

Next is a description of a variation of the first embodiment described above with reference to FIGS. 5 and 6.

In the variations and embodiments given below, members and elements that are the same as or similar to those described above are given the same reference numerals as above, and descriptions of the configurations (and technical effects obtained therefrom) of the members and elements are omitted as appropriate.

In a display unit 101 shown in FIGS. 5 and 6, the lamination order of the light blocking layer 61 and the fluorescent layer 66 is the inverse of that of the first embodiment. That is, in the thickness direction Z of the substrate 11, the fluorescent layer 66 is laminated on the light blocking layer 61. Thus, the light blocking layer 61 is located between the fluorescent layer 66 and the substrate 11. Also, the fluorescent layer 66 is in contact with the light blocking layer front surface 611. With this configuration as well, the same functions and advantageous effects as those of the display unit 100 described above can be obtained.

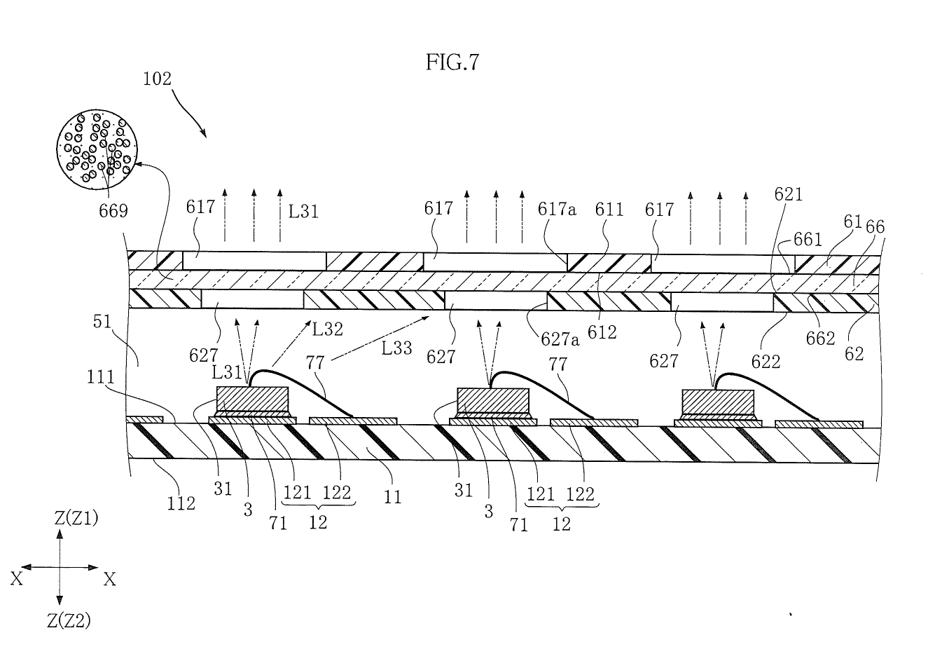

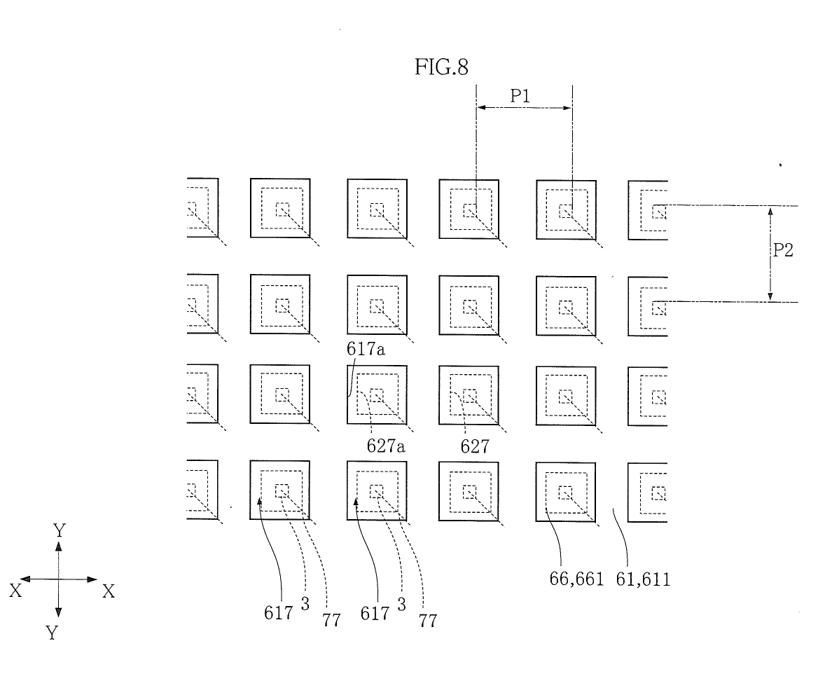

A second embodiment of the present invention will be described next with reference to FIGS. 7 and 8.

A display unit 102 according to the second embodiment includes a substrate 11, a wiring pattern 12, a plurality of LED light sources 3, two light blocking layers (a first light blocking layer 61 and a second light blocking layer 62), a fluorescent layer 66, a plurality of bonding layers 71, a plurality of wires 77, and a control unit (not shown in the diagram in the present embodiment. See reference numeral 78 shown in FIG. 1). The first light blocking layer 61 of the second embodiment corresponds to the light blocking layer 61 of the first embodiment.

The display unit 102 is different from the display unit 100 of the first embodiment described above in that the second light blocking layer 62 is provided. Other members (namely, the substrate 11, the wiring pattern 12, the LED light sources 3, the first light blocking layer 61, the fluorescent layer 66, the bonding layers 71, the wires 77, and the control unit) have already been described above in connection with the display unit 100 in the first embodiment, and thus descriptions thereof are not given here.

The second light blocking layer 62 is disposed so as to be spaced apart from the plurality of LED light sources 3 in the thickness direction Z of the substrate 11. The second light blocking layer 62 is in the form of a film extending parallel to the substrate 11, and has a thickness of, for example, 0.05 to 0.15 mm. In the present embodiment, the second light blocking layer 62 has the same thickness as that of the first light blocking layer 61, but the present invention is not limited thereto. The second light blocking layer 62 is formed by, for example, printing. The second light blocking layer 62 includes portions that each overlap a region between two adjacent LED light sources 3 as viewed in the thickness direction Z.

The second light blocking layer 62 can be made by using a material that blocks part or all of the light L31 emitted from the LED light sources 3. In other words, the second light blocking layer 62 can be configured to block at least part of the light L31. In the present embodiment, the second light blocking layer 62 is configured to completely block the light L31, as with the first light blocking layer 61. The second light blocking layer 62 is made of, for example, a metal (for example, stainless steel) or PET (polyethylene terephthalate). In the case where the second light blocking layer 62 is configured to block part of the light L31, the second light blocking layer 62 is made semi-transparent by using the same method as that described in connection with the light blocking layer 61 in the first embodiment. With the present invention, both the first light blocking layer 61 and the second light blocking layer 62 maybe made semi-transparent. Alternatively, either one of the first light blocking layer 61 and the second light blocking layer 62 may be made semi-transparent, and the other may be made opaque.

The second light blocking layer 62 has a second light blocking layer front surface 621 and a second light blocking layer back surface 622. The second light blocking layer front surface 621 and the second light blocking layer back surface 622 face in opposite directions to each other. To be specific, the second light blocking layer front surface 621 faces in the direction Z1, and the second light blocking layer back surface 622 faces in the direction Z2. The second light blocking layer front surface 621 and the second light blocking layer back surface 622 are both flat.

In the present embodiment, the fluorescent layer 66 is laminated on the second light blocking layer 62. The second light blocking layer 62 and the fluorescent layer 66 are in contact with each other. In the thickness direction Z of the substrate 11, the fluorescent layer 66 is located between the second light blocking layer 62 and the first light blocking layer 61.

A plurality of openings (i.e. second openings) 627 are formed in the second light blocking layer 62. Each second opening 627 has a rectangular shape. The plurality of second openings 627 respectively overlap the plurality of LED light sources 3 as viewed in the thickness direction Z. The fluorescent layer 66 includes areas that respectively overlap the second openings 627 as viewed in the thickness direction Z.

As shown in FIGS. 7 and 8, the second openings 627 each has a smaller areal dimension than that of the first openings 617. Also, each second opening 627 entirely overlaps the corresponding one of the first openings 617 as viewed in the thickness direction Z of the substrate 11. In other words, the entirety of an opening edge 627a of the second opening 627 is located inwardly with respect to an opening edge 617a of the corresponding one of the first openings 617 as viewed in the thickness direction Z of the substrate 11. Alternatively, it is also possible to configure the second openings 627 to have an areal dimension that is greater than or equal to the areal dimension of the first openings 617.

The display unit 102 includes a vacant space 51. The plurality of LED light sources 3 are exposed in the vacant space 51. The upper end of the vacant space 51 is defined by the second light blocking layer 62. The distance from the lower end of the vacant space 51 (the substrate front surface 111) to the upper end of the vacant space 51 (the second light blocking layer back surface 622) is, for example, 0.3 to 0.7 mm.

With the display unit 102 of the second embodiment, the following functions and advantageous effects can be obtained in addition to the functions and advantageous effects described in connection with the display unit 100 of the first embodiment.

In the second embodiment, the second openings 627 are configured to have a smaller areal dimension than that of the first openings 617. This configuration prevents unnecessary light emitted from the LED light sources 3 from entering the fluorescent layer 66 (see L32 shown in FIG. 7). The configuration also prevents light emitted from each LED light source 3 from improperly entering a second opening 627 that is adjacent to the second opening 627 corresponding to the LED light source 3 (see L33 shown in FIG. 7). Accordingly, in the display unit 102, each pixel can be more clearly displayed, and thus images constituted by a plurality of such pixels can have a high definition.

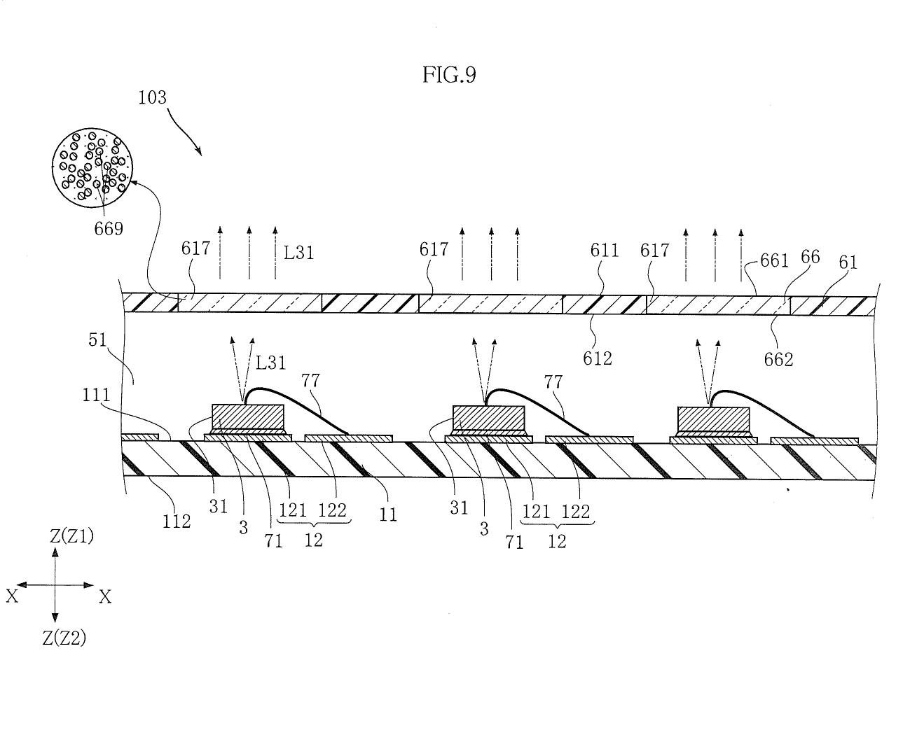

A third embodiment of the present invention will be described with reference to FIG. 9.

A display unit 103 according to the third embodiment includes a substrate 11, a wiring pattern 12, a plurality of LED light sources 3, a light blocking layer (i.e., first light blocking layer) 61, a plurality of fluorescent layers 66, a plurality of bonding layers 71, a plurality of wires 77, and a control unit (not shown in the diagram in the present embodiment. See reference numeral 78 shown in FIG. 1).

The display unit 103 of the third embodiment is different from the display unit 100 of the first embodiment described above in that the fluorescent layers 66 are provided within openings 617 formed in the light blocking layer 61.

The light blocking layer 61 is disposed so as to be spaced apart from the plurality of LED light sources 3 in the thickness direction Z of the substrate 11. The light blocking layer 61 is in the form of a film extending parallel to the substrate 11. The light blocking layer 61 includes portions that each overlap a region between two adjacent LED light sources 3 as viewed in the thickness direction Z.

The light blocking layer 61 has a light blocking layer front surface 611 and a light blocking layer back surface 612. The light blocking layer front surface 611 and the light blocking layer back surface 612 face in opposite directions to each other. To be specific, the light blocking layer front surface 611 faces in the direction Z1, and the light blocking layer back surface 612 faces in the direction Z2. The light blocking layer front surface 611 and the light blocking layer back surface 612 are both flat.

A plurality of openings (i.e., first openings) 617 are formed in the light blocking layer 61. Each opening 617 has a rectangular shape. The plurality of openings 617 respectively overlap the plurality of LED light sources 3 as viewed in the thickness direction Z. The fluorescent layer 66 includes areas that respectively overlap the openings 617 as viewed in the thickness direction Z. Each opening 617 has a size of, for example, 0.5 mm×0.5 mm.

The fluorescent layer 66 contains fluorescent particles 669. To be specific, the fluorescent layer 66 is composed mainly of a resin (for example, epoxy resin, silicone resin, or a polyvinyl-based resin), and the fluorescent particles 669 are mixed with the resin. The fluorescent layer 66 is disposed so as to be spaced apart from the plurality of LED light sources 3 in the thickness direction Z of the substrate 11. The fluorescent layer 66 includes portions that overlap the plurality of LED light sources 3 as viewed in the thickness direction Z.

In the present embodiment, one fluorescent layer 66 is disposed within each opening 617 of the light blocking layer 61. The fluorescent layer 66 is formed by, for example, after the light blocking layer 61 has been formed, filling the openings 617 with a material for forming the fluorescent layer 66.

The fluorescent layer 66 has a fluorescent layer front surface 661 and a fluorescent layer back surface 662. The fluorescent layer front surface 661 and the fluorescent layer back surface 662 face in opposite directions to each other. To be specific, the fluorescent layer front surface 661 faces in the direction Z1, and the fluorescent layer back surface 662 faces in the direction Z2. The fluorescent layer front surface 661 and the fluorescent layer back surface 662 are both flat. Light L31 from the LED light sources 3 enters the fluorescent layer back surface 662. The light L31 that has passed through the fluorescent layer 66 is emitted from the fluorescent layer front surface 661. The fluorescent layer front surface 661 is flush with the light blocking layer front surface 611, and the fluorescent layer back surface 662 is flush with the light blocking layer back surface 612. The display unit 103 includes a vacant space 51. The plurality of LED light sources 3 are exposed in the vacant space 51. The upper end of the vacant space 51 is defined by the fluorescent layer 66 and the first light blocking layer 61. The distance from the lower end of the vacant space 51 (the substrate front surface 111) to the upper end of the vacant space 51 (the light blocking layer back surface 612) is, for example, 0.3 to 0.7 mm.

In the present embodiment, the fluorescent layer 66 is located within the openings 617. This configuration is advantageous in reducing the thickness of the display unit because the thickness of the fluorescent layer 66 and the thickness of the light blocking layer 61 are not included in the dimension in the thickness direction Z.

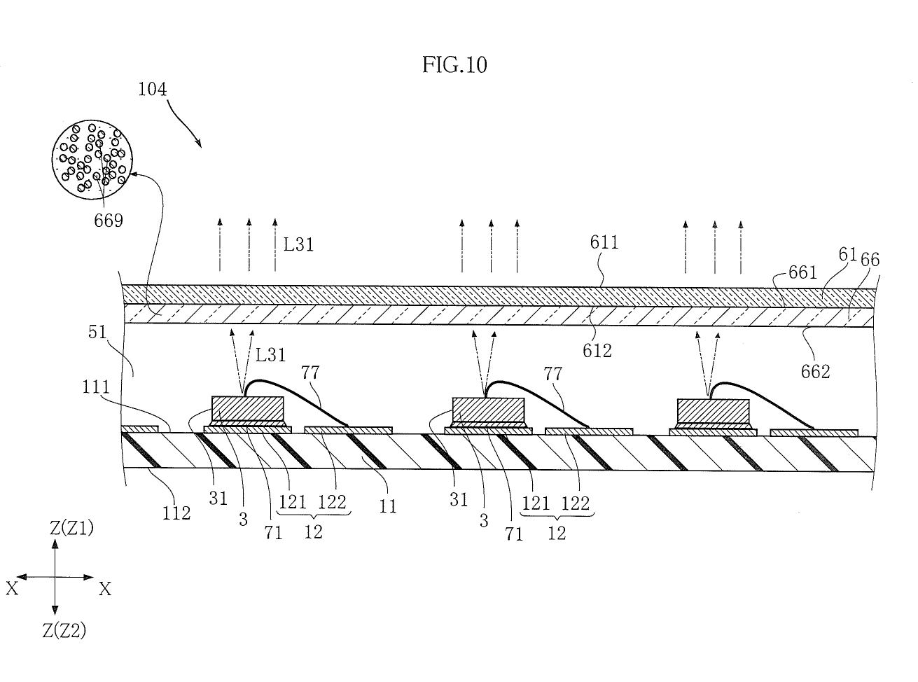

A fourth embodiment of the present invention will be described with reference to FIG. 10.

A display unit 104 according to the fourth embodiment includes a substrate 11, a wiring pattern 12, a plurality of LED light sources 3, a light blocking layer (i.e., first light blocking layer) 61, a fluorescent layer 66 , a plurality of bonding layers 71, a plurality of wires 77, and a control unit (not shown in the diagram in the present embodiment. See reference numeral 78 shown in FIG. 1).

In the display unit 104, the light blocking layer 61 is semi-transparent, and is configured to allow part of light emitted from the LED light sources 3 to pass therethrough. The light blocking layer 61 of the present embodiment is a single flat plate having an overall uniform thickness, with no openings passing therethrough. As viewed in the thickness direction Z, the light blocking layer 61 overlaps the plurality of LED light sources 3. The fluorescent layer 66 is located between the light blocking layer 61 and the substrate 11. Alternatively, the light blocking layer 61 may be disposed between the fluorescent layer 66 and the substrate 11.

Functions and advantageous effects of the present embodiment will be described next.

The display unit 104 of the fourth embodiment includes the semi-transparent light blocking layer 61 that blocks part of light L31 emitted from the LED light sources 3. The light blocking layer 61 includes an area that overlaps a region between each two adjacent LED light sources 3 as viewed in the thickness direction Z of the substrate 11. Accordingly, with the configuration of the present embodiment as well, high-definition images can be displayed at a desired image density, as described in connection with the display unit 100 in the first embodiment. Also, it is unnecessary to form openings in the light blocking layer 61, and thus the display unit 104 can be efficiently produced.

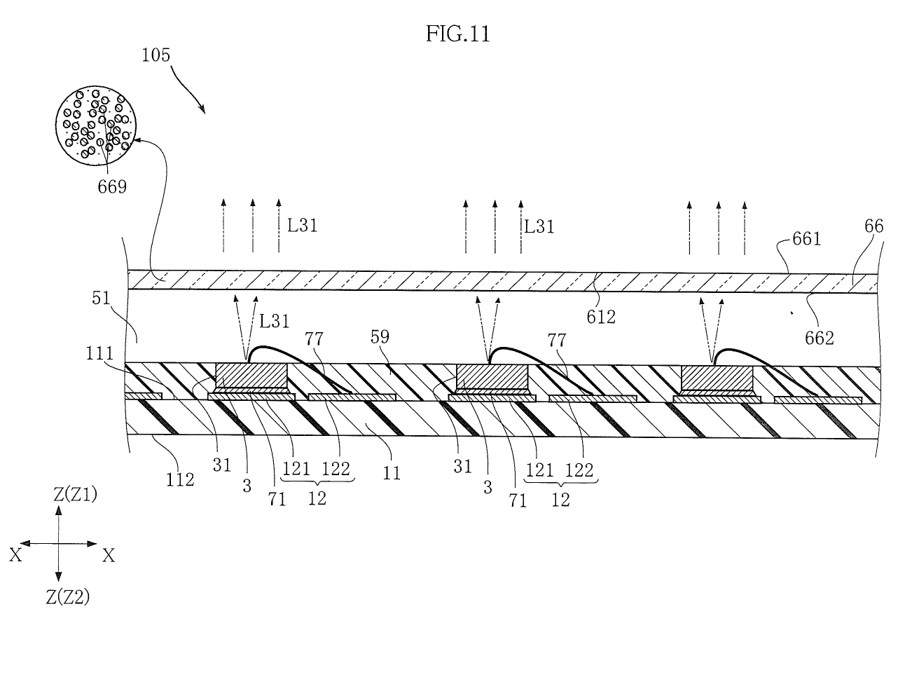

A fifth embodiment of the present invention will be described with reference to FIG. 11.

A display unit 105 according to the fifth embodiment includes a substrate 11, a wiring pattern 12, a plurality of LED light sources 3, a light blocking portion 59, a fluorescent layer 66, a plurality of bonding layers 71, a plurality of wires 77, and a control unit (not shown in the diagram in the present embodiment. See reference numeral 78 shown in FIG. 1). The display unit 105 of the present embodiment basically has the same configuration as that of the display unit 100 of the first embodiment, except that the light blocking portion 59 is provided, instead of the light blocking layer 61.

The light blocking portion 59 is formed on the substrate 11, and is interposed between the plurality of LED light sources 3. Also, the light blocking portion 59 is in contact with the side surfaces 31 of each LED light source 3. In the present embodiment, the upper surface of the light blocking portion 59 is flush with the upper surface of each LED light source 3, and the upper surface of each LED light source 3 is not covered by the light blocking portion 59. The light blocking portion 59 is made of an insulating material obtained by, for example, mixing titanium oxide particles with silicone resin. In the present embodiment, the light blocking portion 59 is white, but instead, the light blocking portion 59 may be of any other color (for example, black). The light blocking portion 59 can be formed by, for example, applying a resin onto the substrate 11 after the plurality of LED light sources 3 have been disposed on the substrate 11.

Functions and advantageous effects of the fifth embodiment will be described next.

In the present embodiment, the light blocking portion 59 is interposed between a plurality of LED light sources 3, and covers the side surfaces 31 of each LED light source 3. With this configuration, it is possible to reduce light traveling in the lateral direction from the LED light sources 3. This contributes to avoiding an unwanted situation in which, for example, when of two adjacent pixels (namely, a first pixel and a second pixel), the first pixel is illuminated and the second pixel is extinguished, the second pixel becomes too bright.

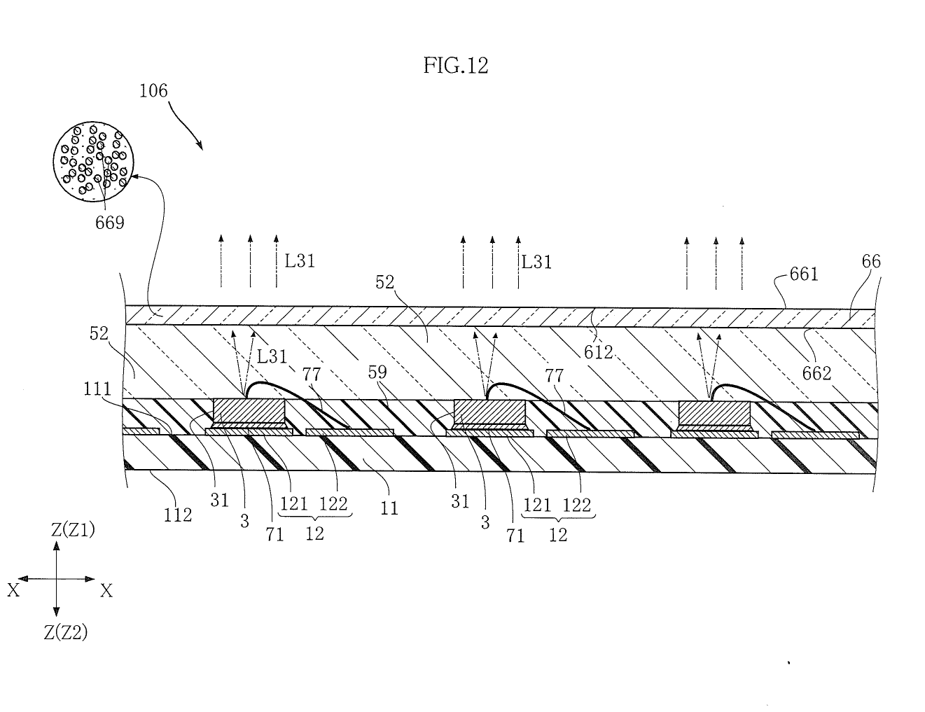

A sixth embodiment of the present invention will be described with reference to FIG. 12.

A display unit 106 according to the sixth embodiment is different from the display unit 105 of the fifth embodiment described above in that a light transmitting resin portion 52 that covers the plurality of LED light sources 3 is provided.

The light transmitting resin portion 52 is made of a material that allows light emitted from the LED light sources 3 to pass therethrough. The light transmitting resin portion 52 may be completely transparent, or may be semi-transparent. The light transmitting resin portion 52 is in contact with the fluorescent layer 66. The light transmitting resin portion 52 is also in contact with the light blacking portion 59. In the present embodiment, the light transmitting resin portion 52 is interposed between the light blocking portion 59 and the fluorescent layer 66, which contributes to an improvement in the mechanical strength of the display unit 106. Also, the light transmitting resin portion 52 covers the upper surface of each LED light source 3 and at least part of each wire, and thus the light transmitting resin portion 52 can protect them.

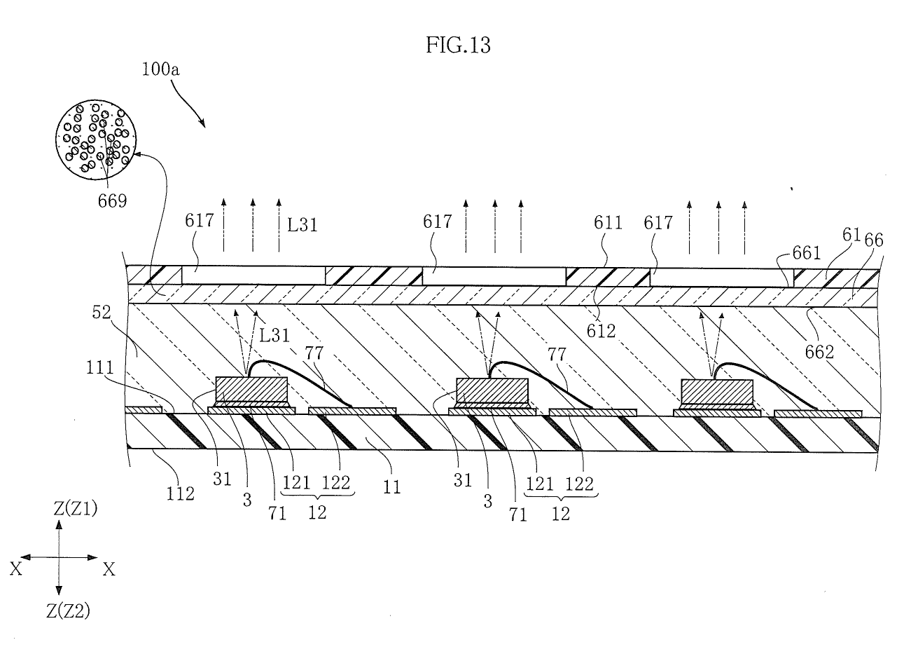

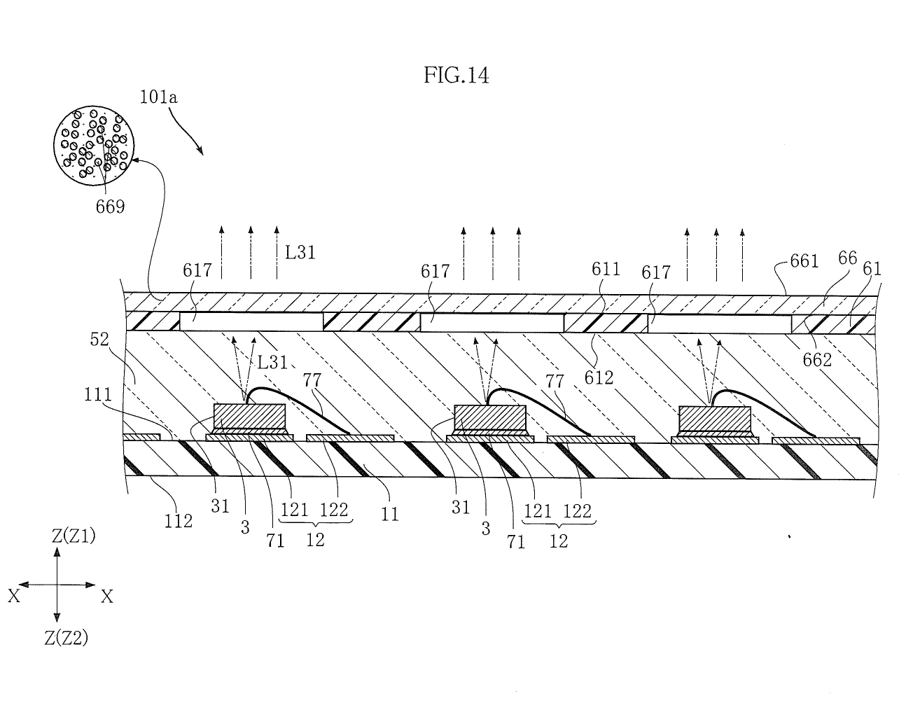

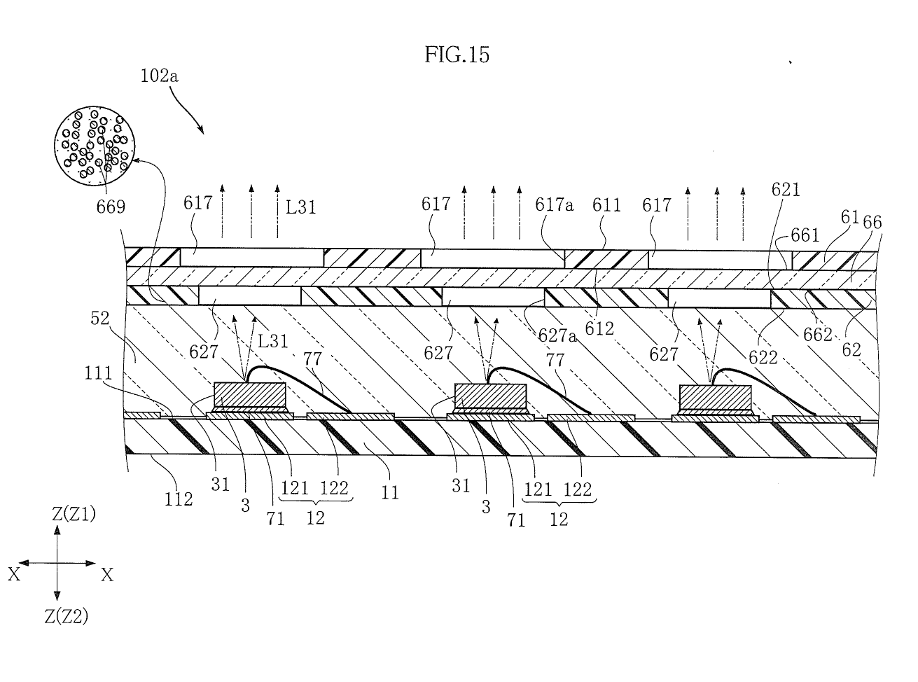

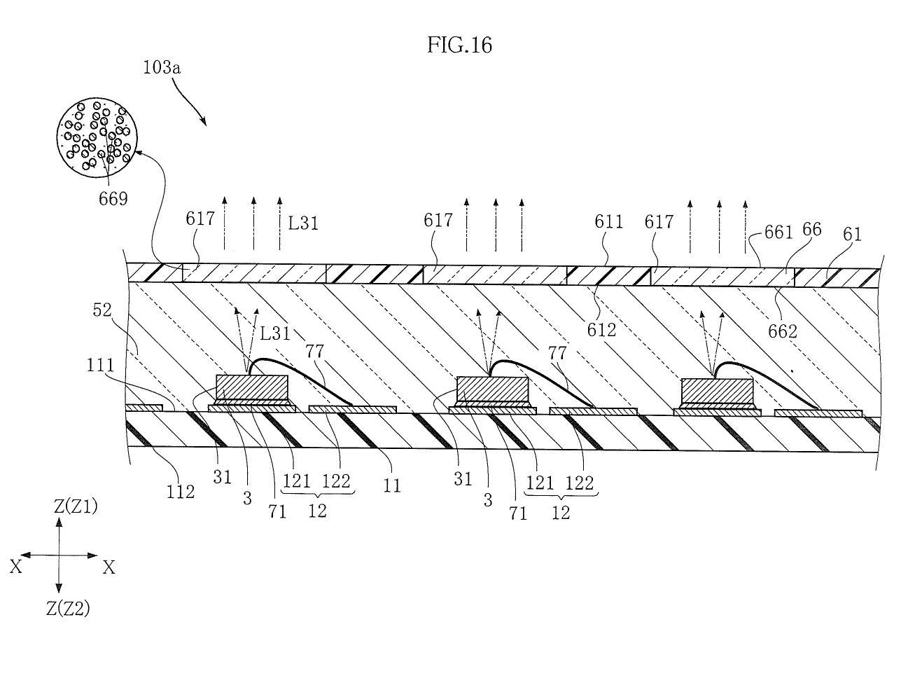

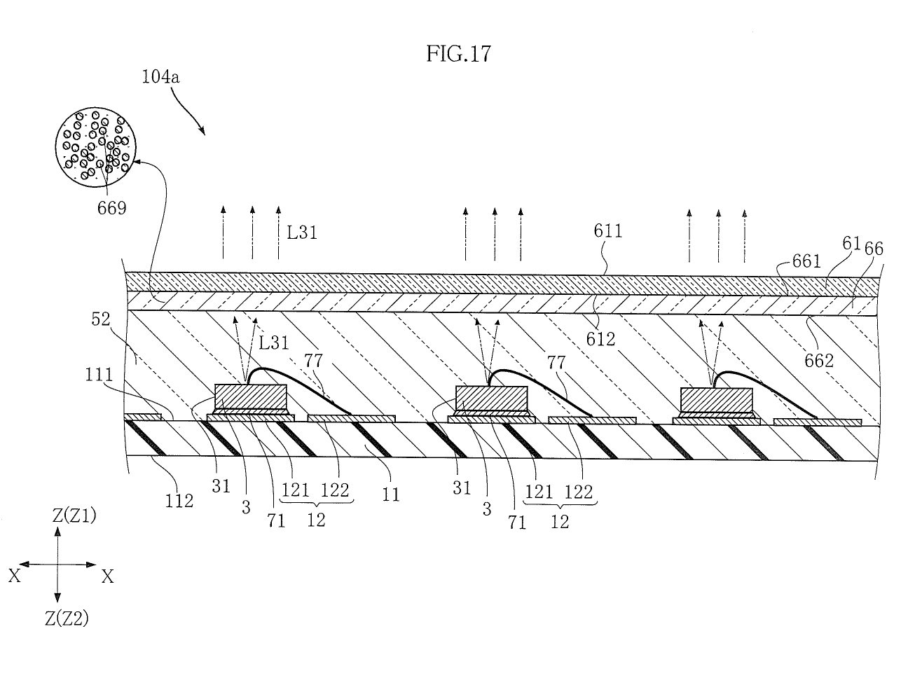

As variations of the display units 100 to 104 described above, each display unit may be configured to include the light transmitting resin portion 52 shown in FIG. 12. A display unit 100a shown in FIG. 13 is a variation of the display unit 100 shown in FIG. 2. A display unit 101a shown in FIG. 14 is a variation of the display unit 101 shown in FIG. 5. A display unit 102a shown in FIG. 15 is a variation of the display unit 102 shown in FIG. 7. A display unit 103a shown in FIG. 16 is a variation of the display unit 103 shown in FIG. 9. A display unit 104a shown in FIG. 17 is a variation of the display unit 104 shown in FIG. 10.

The present invention is not limited to the embodiments given above. Specific configurations of the constituent elements of the present invention can be designed and changed in various ways. For example, the display units according to the embodiments and variations given above include a fluorescent layer 66, but they may be configured to not include such a fluorescent layer.

The following is a list of variations of the present invention, which are provided as appendixes.

### [Appendix 1]

A display unit comprising:

a substrate;

a plurality of LED light sources arranged in a matrix on the substrate; and

a fluorescent layer that overlaps the plurality of LED light sources as viewed in a thickness direction of the substrate,

wherein the fluorescent layer is disposed so as to be spaced apart from the plurality of LED light sources in the thickness direction of the substrate.

### [Appendix 2]

The display unit according to Appendix 1, further comprising a light blocking portion formed on the substrate,

wherein the light blocking portion is interposed between the plurality of LED light sources.

### [Appendix 3]

The display unit according to Appendix 2,

wherein the light blocking portion is in contact with a side surface of one of the plurality of LED light sources.

### [Appendix 4]

The display unit according to Appendix 1, further comprising a light transmitting resin portion interposed between the substrate and the fluorescent layer,

wherein the light transmitting resin portion covers the plurality of LED light sources.

### [Appendix 5]

The display unit according to Appendix 1,

wherein the plurality of LED light sources are exposed in a vacant space.

### [Appendix 6]

The display unit according to Appendix 1, further comprising a first light blocking layer that blocks at least part of the light emitted from the plurality of LED light sources,

wherein the first light blocking layer includes an area that overlaps a region between two adjacent LED light sources among the plurality of LED light sources as viewed in the thickness direction of the substrate.

### [Appendix 7]

The display unit according to Appendix 6,

wherein the first light blocking layer is in a form of a film extending parallel to the substrate.

### [Appendix 8]

The display unit according to Appendix 6,

wherein the first light blocking layer is disposed so as to be spaced apart from the plurality of LED light sources in the thickness direction of the substrate.

### [Appendix 9]

The display unit according to Appendix 6,

wherein the first light blocking layer is configured to completely block the light emitted from the plurality of LED light sources.

### [Appendix 10]

The display unit according to Appendix 6,

wherein the first light blocking layer is semi-transparent.

### [Appendix 11]

The display unit according to Appendix 10,

wherein the first light blocking layer includes areas that overlap the plurality of LED light sources as viewed in the thickness direction of the substrate.

### [Appendix 12]

The display unit according to Appendix 6,

wherein the fluorescent layer is laminated on the first light blocking layer.

### [Appendix 13]

The display unit according to Appendix 12,

wherein the fluorescent layer is located between the first light blocking layer and the substrate in the thickness direction of the substrate.

### [Appendix 14]

The display unit according to Appendix 12,

wherein the first light blocking layer is located between the fluorescent layer and the substrate in the thickness direction of the substrate.

### [Appendix 15]

The display unit according to Appendix 6, further comprising a second light blocking layer that blocks at least part of the light emitted from the plurality of LED light sources,

wherein the second light blocking layer includes an area that overlaps a region between two adjacent LED light sources among the plurality of LED light sources as viewed in the thickness direction of the substrate.

### [Appendix 16]

The display unit according to Appendix 15,

wherein the fluorescent layer is located between the first light blocking layer and the second light blocking layer in the thickness direction of the substrate.

### [Appendix 17]

The display unit according to Appendix 6,

wherein a plurality of first openings are formed in the first light blocking layer, and the plurality of first openings respectively overlap the plurality of LED light sources as viewed in the thickness direction of the substrate.

### [Appendix 18]

The display unit according to Appendix 15,

wherein a plurality of second openings are formed in the second light blocking layer, and

the plurality of second openings respectively overlap the plurality of LED light sources as viewed in the thickness direction of the substrate.

### [Appendix 19]

The display unit according to Appendix 15,

wherein a plurality of first openings are formed in the first light blocking layer,

the plurality of first openings respectively overlap the plurality of LED light sources as viewed in the thickness direction of the substrate,

a plurality of second openings are formed in the second light blocking layer,

the plurality of second openings respectively overlap the plurality of LED light sources as viewed in the thickness direction of the substrate, and

the first openings have a larger areal dimension than the second openings.

### [Appendix 20]

The display unit according to Appendix 19,

wherein the entirety of each of the second openings is located within a corresponding one of the first openings as viewed in the thickness direction of the substrate.

### [Appendix 21]

The display unit according to Appendix 17,

wherein the fluorescent layer is located within each of the plurality of first openings.

### [Appendix 22]

The display unit according to Appendix 1,

wherein the plurality of LED light sources are spaced apart from each other at a spacing pitch of 0.5 to 1.2 mm.

### [Appendix 23]

The display unit according to Appendix 1,

wherein a spaced distance between the fluorescent layer and the substrate is 0.3 to 0.7 mm.

### [Appendix 24]

The display unit according to Appendix 1,

wherein the plurality of LED light sources are bare chip LEDs.

### [Appendix 25]

The display unit according to Appendix 1,

wherein the plurality of LED light sources each emit blue light.

### [Appendix 26]

The display unit according to Appendix 1, further comprising a bonding layer and a wiring pattern formed on the substrate,

wherein the wiring pattern and any one of the plurality of LED light sources are bonded to each other via the bonding layer.

### [Appendix 27]

The display unit according to Appendix 26, further comprising a wire bonded to the wiring pattern and any one of the LED light sources.

### [Appendix 28]

The display unit according to Appendix 1, further comprising a control unit that performs control so as to selectively illuminate the plurality of LED light sources.

1. A display unit comprising:
a substrate;
a plurality of LED light sources arranged in a matrix on the substrate; and
a first light blocking layer that blocks at least part of light emitted from the plurality of LED light sources,
wherein the first light blocking layer includes an area that overlaps a region between two adjacent LED light sources among the plurality of LED light sources as viewed in a thickness direction of the substrate.

2. The display unit according to claim 1, wherein the first light blocking layer is in a form of a film extending parallel to the substrate.

3. The display unit according to claim 1, wherein the first light blocking layer is disposed so as to be spaced apart from the plurality of LED light sources in the thickness direction of the substrate.

4. The display unit according to claim 1, wherein the first light blocking layer is configured to completely block the light emitted from the plurality of LED light sources.

5. The display unit according to claim 1, wherein the first light blocking layer is semi-transparent.

6. The display unit according to claim 5, wherein the first light blocking layer includes areas that overlap the plurality of LED light sources as viewed in the thickness direction of the substrate.

7. The display unit according to claim 1, further comprising a fluorescent layer that overlaps the plurality of LED light sources as viewed in the thickness direction of the substrate.

8. The display unit according to claim 7, wherein the fluorescent layer is disposed so as to be spaced apart from the plurality of LED light sources in the thickness direction of the substrate .

9. The display unit according to claim 7, wherein the fluorescent layer is laminated on the first light blocking layer.

10. The display unit according to claim 9, wherein the fluorescent layer is located between the first light blocking layer and the substrate in the thickness direction of the substrate.

11. The display unit according to claim 9, wherein the first light blocking layer is located between the fluorescent layer and the substrate in the thickness direction of the substrate.

12. The display unit according to claim 7, further comprising a second light blocking layer that blocks at least part of the light emitted from the plurality of LED light sources,
wherein the second light blocking layer includes an area that overlaps a region between two adjacent LED light sources among the plurality of LED light sources as viewed in the thickness direction of the substrate.

13. The display unit according to claim 12, wherein the fluorescent layer is located between the first light blocking layer and the second light blocking layer in the thickness direction of the substrate.

14. The display unit according to claim 7, wherein a plurality of first openings are formed in the first light blocking layer, and
the plurality of first openings respectively overlap the plurality of LED light sources as viewed in the thickness direction of the substrate.

15. The display unit according to claim 12, wherein a plurality of second openings are formed in the second light blocking layer, and
the plurality of second openings respectively overlap the plurality of LED light sources as viewed in the thickness direction of the substrate.

16. The display unit according to claim 12, wherein a plurality of first openings are formed in the first light blocking layer, the plurality of first openings respectively overlapping the plurality of LED light sources as viewed in the thickness direction of the substrate,
a plurality of second openings are formed in the second light blocking layer, the plurality of second openings respectively overlapping the plurality of LED light sources as viewed in the thickness direction of the substrate, and
the first openings have a larger areal dimension than the second openings.

17. The display unit according to claim 16, wherein the entirety of each of the second openings is located within a corresponding one of the first openings as viewed in the thickness direction of the substrate.

18. The display unit according to claim 14, wherein the fluorescent layer is located within each of the plurality of first openings.

19. The display unit according to claim 1, wherein the plurality of LED light sources are spaced apart from each other at a spacing pitch of 0.5 to 1.2 mm.

20. The display unit according to claim 1, wherein a spaced distance between the first light blocking layer and the substrate is 0.3 to 0.7 mm.

21. The display unit according to claim 1, wherein the plurality of LED light sources are bare chip LEDs.

22. The display unit according to claim 1, wherein the plurality of LED light sources each emit blue light.

23. The display unit according to claim 1, wherein the plurality of LED light sources are exposed in a vacant space.

24. The display unit according to claim 1, further comprising a light transmitting resin portion interposed between the substrate and the first light blocking layer,
wherein the light transmitting resin portion covers the plurality of LED light sources.

25. The display unit according to claim 1, further comprising: a bonding layer; and a wiring pattern formed on the substrate,
wherein the wiring pattern and any one of the plurality of LED light sources are bonded to each other via the bonding layer.

26. The display unit according to claim 25, further comprising a wire bonded to the wiring pattern and any one of the LED light sources.

27. The display unit according to claim 1, further comprising a control unit that performs control so as to selectively illuminate the plurality of LED light sources.
